(19) United States
(12) Patent Application Publication
(10) Pub. No.: US 2026/0173416 A1
(43) Pub. Date: Jun. 18, 2026

(54) SEMICONDUCTOR STRUCTURE AND MANUFACTURING METHOD THEREFOR, AND SEMICONDUCTOR DEVICE

(71) Applicant: CXMT Corporation, Hefei City (CN)

(72) Inventors: Xiaoping LIU, Hefei City (CN); Dan XU, Hefei City (CN); MING-HUI HUANG, Hefei City (CN)

(73) Assignee: CXMT Corporation, Hefei City (CN)

(21) Appl. No.: 19/424,207

(22) Filed: Dec. 18, 2025

Related U.S. Application Data
(63) Continuation of application No. PCT/CN2025/080728, filed on Mar. 5, 2025.

(30) Foreign Application Priority Data
Dec. 12, 2024 (CN) 202411834462.3

(51) Int. Cl. H10D 1/68; H10D 1/00; H10W 70/05; H10W 70/652

(52) U.S. Cl. CPC H10D 1/716; H10D 1/043; H10D 1/714; H10W 70/05; H10W 70/652

(57) ABSTRACT

A semiconductor structure includes: an interposer, wherein the interposer has a trench array including multiple trenches extending from a top surface of the interposer toward an interior of the interposer, the multiple trenches further extend in a preset direction parallel to the top surface of the interposer; a capacitor located in the trenches, wherein the capacitor includes a first electrode layer, a first capacitor dielectric layer, and a second electrode layer being sequentially stacked, the first capacitor dielectric layer covers a surface of the first electrode layer, and the second electrode layer covers a surface of the first capacitor dielectric layer; lead-out electrode layers located in the interposer, wherein the lead-out electrode layers are electrically connected to the first electrode layer and/or the second electrode layer and extend in the preset direction. The semiconductor structure has the advantages of large capacity, fast charge and discharge, high integration, and high reliability.

### CROSS-REFERENCE TO RELATED APPLICATIONS

This application is a continuation of International Patent Application No. PCT/CN2025/080728, filed on Mar. 5, 2025, which claims priority to Chinese Patent Application No. 202411834462.3, filed on Dec. 12, 2024. The disclosures of the above-referenced applications are hereby incorporated by reference in their entirety.

### TECHNICAL FIELD

Embodiments of the present disclosure relate to the field of semiconductor technologies, and in particular, to a semiconductor structure and a manufacturing method therefor, and a semiconductor device.

### BACKGROUND

To improve integration of a semiconductor structure, many chips may be stacked and soldered together to form, e.g., a 3-dimensional stack (3DS) memory. Therefore, an original 2D layout may be extended to 2.5D (between 2D and 3D packages) or 3D, thereby greatly increasing a chip density. In the field of advanced packaging technologies, especially in 2.5D and 3D packaging technologies, interposer packaging is widely used. That is, multiple chips (dies) are arranged on a substrate through an interposer device, and different dies may receive signals from other chips or transmit signals to other chips through the interposer device, thereby increasing a signal density of an entire package and achieving an advantage of reducing an overall volume.

In the interposer device, to maintain signal stability, a deep trench capacitor (DTC) structure is usually employed to prevent signal lines from interfering with each other. However, there is a clear limitation on a structural design of a deep trench capacitor structure in the conventional technology, and performance still needs to be further enhanced.

### SUMMARY

According to a first aspect of an embodiment of the present disclosure, a semiconductor structure is provided, including: an interposer, where the interposer has a trench array including multiple trenches extending from a top surface of the interposer toward an interior of the interposer, and the plurality of trenches further extend in a preset direction parallel to the top surface of the interposer; a capacitor located in the trenches, where the capacitor includes at least a first electrode layer, a first capacitor dielectric layer, and a second electrode layer that are sequentially stacked, the first capacitor dielectric layer covers a surface of the first electrode layer, and the second electrode layer covers a surface of the first capacitor dielectric layer; and lead-out electrode layers located in the interposer. The lead-out electrode layers are electrically connected to the first electrode layer and/or the second electrode layer and extend in the preset direction.

According to a second aspect of an embodiment of the present disclosure, a manufacturing method for a semiconductor structure is provided, including the steps as follows. An interposer is provided. Lead-out electrode layers and a trench array including multiple trenches extending from a top surface of the interposer toward an interior of the interposer are formed in the interposer. The plurality of trenches further extend in a preset direction parallel to the top surface of the interposer. A capacitor including at least a first electrode layer, a first capacitor dielectric layer, and a second electrode layer that are sequentially stacked is formed in the trenches. The first capacitor dielectric layer covers a surface of the first electrode layer, and the second electrode layer covers a surface of the first capacitor dielectric layer. The lead-out electrode layers are electrically connected to the first electrode layer and/or the second electrode layer and extend in the preset direction.

According to a third aspect of an embodiment of the present disclosure, a semiconductor device is provided, including: the semiconductor structure according to any one of the aforementioned embodiments; and chips located on the semiconductor structure. The chips are electrically connected to the semiconductor structure through solder ball bumps and/or pads.

### BRIEF DESCRIPTION OF DRAWINGS

FIG. 1 is a schematic diagram of providing an interposer according to example Embodiment 1;

FIG. 2 is a schematic diagram of forming a first lead-out electrode layer according to example Embodiment 1;

FIG. 3 is a schematic diagram of forming trenches according to example Embodiment 1;

FIG. 4 is a schematic diagram of forming a capacitor according to example Embodiment 1;

FIG. 5 is a schematic diagram of forming contact members according to example Embodiment 1;

FIG. 6 is a schematic diagram of forming a contact member according to another example Embodiment 1;

FIG. 7 is a schematic diagram of forming a second lead-out electrode layer according to example Embodiment 2;

FIG. 8 is a schematic diagram of forming contact members according to example Embodiment 2;

FIG. 9 is a schematic diagram of forming contact members according to another example Embodiment 2;

FIG. 10 is a schematic diagram of forming trenches according to example Embodiment 3;

FIG. 11 is a schematic diagram of forming a capacitor and a lead-out electrode layer according to example Embodiment 3;

FIG. 12 is a schematic diagram of forming contact members according to example Embodiment 3;

FIG. 13 is a schematic diagram of forming contact members according to another example Embodiment 3;

FIG. 14 is a schematic diagram of forming trenches according to example Embodiment 4;

FIG. 15 is a schematic diagram of forming a capacitor and a lead-out electrode layer according to example Embodiment 4;

FIG. 16 is a schematic diagram of forming contact members according to example Embodiment 4;

FIG. 17 is a schematic diagram of forming a capacitor and a lead-out electrode layer according to example Embodiment 5;

FIG. 18 is a schematic diagram of forming contact members according to example Embodiment 5;

FIG. 19 is a schematic diagram of forming a bottom dielectric layer according to example Embodiment 6;

FIG. 20 is a schematic diagram of arrangement of a trench array according to an example embodiment; and

FIG. 21 is a schematic diagram of a semiconductor device according to an example embodiment.

### DESCRIPTION OF EMBODIMENTS

The technical solutions of the present disclosure are further described below in detail with reference to the accompanying drawings and the embodiments. Although example implementation methods of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing objectives of the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily indicate a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be arbitrarily combined when there is no conflict.

In related technologies, DTC structures each are basically in the shape of a deep hole, and are usually synchronously manufactured by a process of forming through silicon vias (TSVs) in an interposer. The inventors of this application have found that with the development of 2.5D packaging technology, after a device dimension is further reduced, a capacitor area of a DTC structure is reduced, and it is increasingly difficult to increase a capacitance density, which is accompanied by increasingly severe stress and other problems during supporting. Therefore, it is increasingly important to find a new DTC structure design solution.

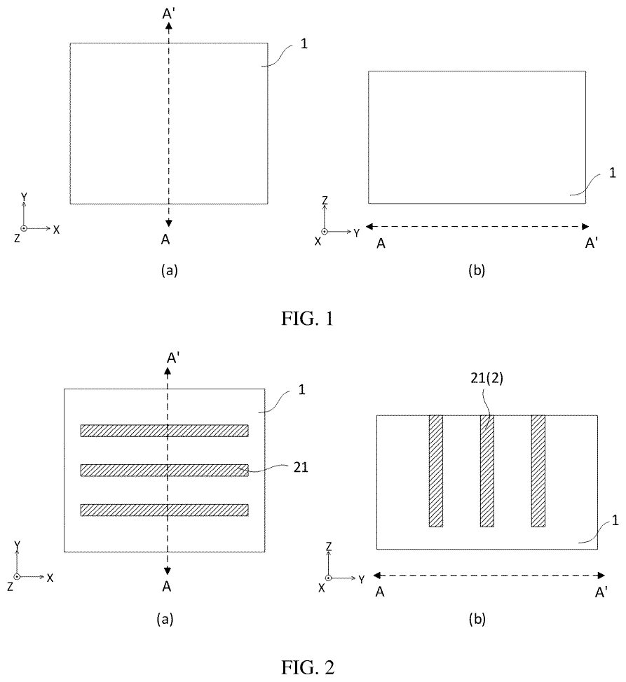

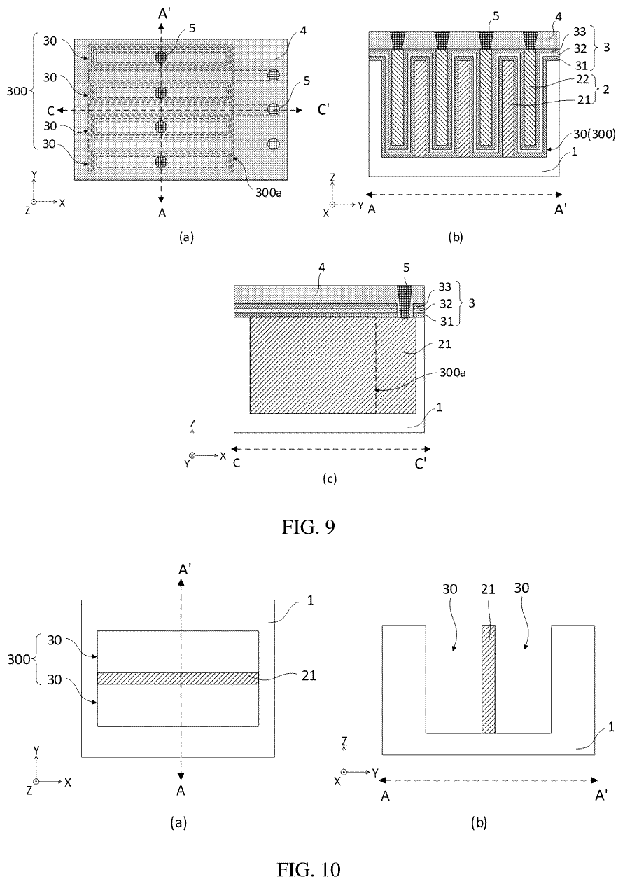

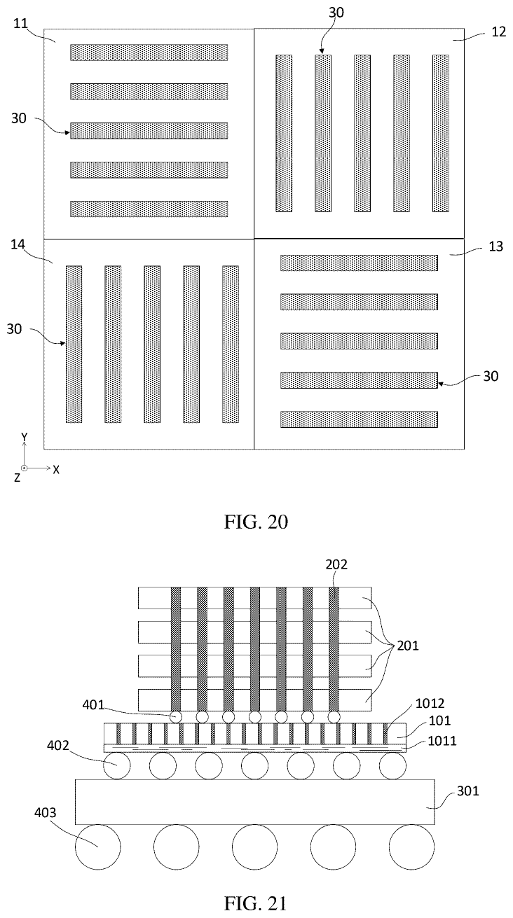

In view of the above technical problems, the present disclosure provides a semiconductor structure and a manufacturing method therefor, and a semiconductor device. The semiconductor structure and the manufacturing method therefor, and the semiconductor device provided by the present disclosure as examples are specifically described below with reference to FIG. 1 to FIG. 21. FIG. 1 to FIG. 19 are schematic diagrams of a manufacturing method for a semiconductor structure according to multiple example embodiments of the present disclosure. FIG. 20 is a schematic diagram of arrangement of a trench array according to an example embodiment of the present disclosure. FIG. 9 is a schematic diagram of a semiconductor device according to an example embodiment of the present disclosure.

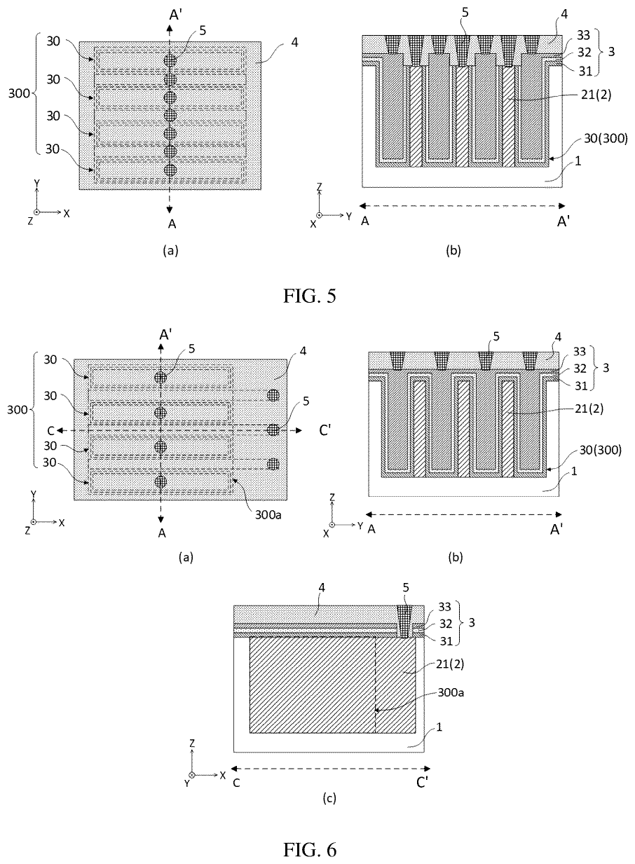

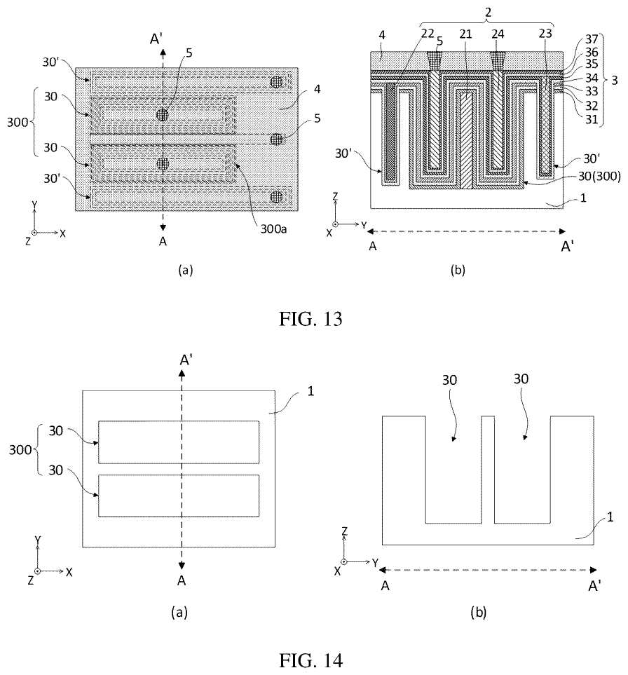

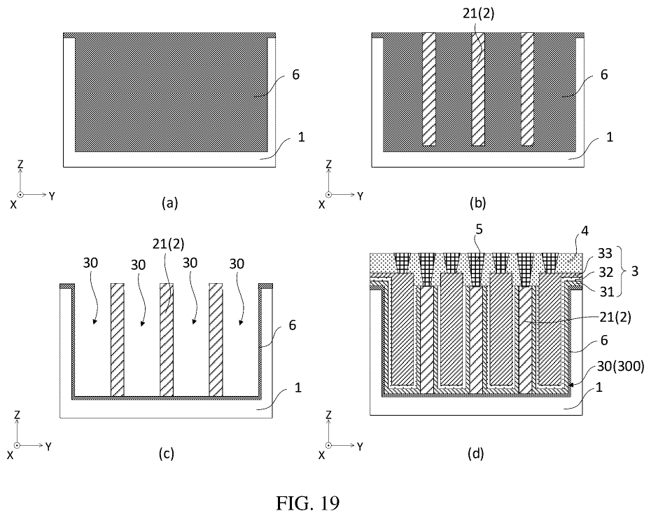

In an example embodiment of the present disclosure, a semiconductor structure is provided, as shown in FIG. 5, FIG. 6, FIG. 8, FIG. 9, FIG. 12, FIG. 13, FIG. 16, FIG. 18, or FIG. 19(d). The semiconductor structure includes: an interposer 1, where the interposer 1 has a trench array 300 including multiple trenches 30 extending from a top surface of the interposer 1 toward an interior of the interposer 1, and the plurality of trenches 30 further extend in a preset direction parallel to the top surface of the interposer 1; a capacitor 3 located in the trenches 30, where the capacitor 3 includes a first electrode layer 31, a first capacitor dielectric layer 32, and a second electrode layer 33 that are sequentially stacked, the first capacitor dielectric layer 32 covers a surface of the first electrode layer 31, and the second electrode layer 33 covers a surface of the first capacitor dielectric layer 32; and lead-out electrode layers 2 located in the interposer 1. The lead-out electrode layers 2 are electrically connected to the first electrode layer 31 and/or the second electrode layer 33 and extend in the preset direction. It should be noted that in an example embodiment of the present disclosure, the preset direction is the same as or opposite to an X direction. It should be noted that an X direction, a Y direction, and a Z direction in all accompanying drawings of the specification of the present disclosure are perpendicular to each other.

In an example embodiment of the present disclosure, an Si interposer is adopted as the interposer 1. The Si interposer may be made of at least one of the following materials: silicon, germanium, silicon on insulator (SOI), stacked silicon on insulator (SSOI), stacked silicon-germanium on insulator (S-SiGeOI), silicon-germanium on insulator (SiGeOI), germanium on insulator (GeOI), and other semiconductor materials or a combination of III-V materials and organic materials.

The trenches 30 are located in the interposer 1, and extend from the top surface of the interposer 1 toward the interior of the interposer 1. That is, an opening of each of the trenches 30 is at the top surface of the interposer 1, and a depth direction of the trench 30 is perpendicular to a plane on which the top surface of the interposer 1 is located, to face the interior of the interposer 1, and is opposite to the Z direction in the figure. Parallel to the plane on which the top surface of the interposer 1 is located, multiple trenches 30 extend in a preset direction and are arranged at intervals in a direction perpendicular to the preset direction to form a trench array 300. That is, as shown in the figure, the multiple trenches 30 in the trench array 300 extend in the X direction or a reverse direction thereof and are arranged at intervals in the Y direction or a reverse direction thereof. In some embodiments, there are two or more trenches 30 in the trench array 300. In some embodiments, a schematic cross-sectional view of each of the trenches 30 is rectangular. In some other embodiments, a schematic cross-sectional view of each of the trenches 30 is trapezoidal. For example, the opening dimension of the trench 30 is larger than the bottom dimension thereof, or the bottom dimension of the trench 30 is larger than the opening dimension thereof. In another embodiment, the bottom of each of the trenches 30 is in an arc shape recessed toward the interior of the interposer 1. A direction of the opening dimension or the bottom dimension is parallel to the top surface of the interposer 1 and is perpendicular to the preset direction in the aforementioned embodiment. That is, the direction of the opening dimension or the bottom dimension is the same as or opposite to the Y direction.

The capacitor 3 is located in the trenches 30, and includes a first electrode layer 31, a first capacitor dielectric layer 32, and a second electrode layer 33 that are sequentially stacked. The first capacitor dielectric layer 32 covers a surface of the first electrode layer 31, and the second electrode layer 33 covers a surface of the first capacitor dielectric layer 32. In some embodiments, the capacitor 3 further includes one or more other electrode layers besides the first electrode layer 31 and the second electrode layer 33, and adjacent electrode layers are separated by the first capacitor dielectric layer 32 or another capacitor dielectric layer. For example, the capacitor 3 in FIG. 12, FIG. 13, FIG. 16, and FIG. 18 further includes a third electrode layer 35 and a fourth electrode layer 37. A second capacitor dielectric layer 34 separates the second electrode layer 33 from the third electrode layer 35, and a third capacitor dielectric layer 36 separates the third electrode layer 35 from the fourth electrode layer 37. The second capacitor dielectric layer 34 covers a surface of the second electrode layer 33, and the third electrode layer 35 covers a surface of the second capacitor dielectric layer 34. The third capacitor dielectric layer 36 covers a surface of the third electrode layer 35, and the fourth electrode layer 37 covers a surface of the third capacitor dielectric layer 36. The capacitors 3 further extend to a top surface of the interposer 1 outside the trenches 30. In some embodiments, capacitors 3 located in adjacent trenches 30 are connected into a whole. That is, film layers (e.g., the first electrode layer 31, the first capacitor dielectric layer 32, and the second electrode layer 33) of the capacitors 3, which are located on the top surface of the interposer 1 between adjacent trenches 30, are connected into a whole. In some other embodiments, the capacitors 3 located in adjacent trenches 30 are isolated from each other. That is, the film layers (e.g., the first electrode layer 31, the first capacitor dielectric layer 32, and the second electrode layer 33) of the capacitors 3, which are located on the top surface of the interposer 1 between adjacent trenches 30, are disconnected to remain isolated, so as to improve flexibility and controllability of the semiconductor structure.

In some embodiments, the first electrode layer 31, the second electrode layer 33, and/or other electrode layers (e.g., the third electrode layer 35 and the fourth electrode layer 37) each may be made of at least one or a combination of more of doped silicon, titanium nitride (TiN), silicon doped titanium nitride (TiSiN), titanium (Ti), tungsten (W), tungsten nitride (WN), and silicon doped tungsten nitride (WSiN). The first capacitor dielectric layer 32 and/or other capacitor dielectric layers (e.g., the second capacitor dielectric layer 34 and the third capacitor dielectric layer 36) each may be made of at least one or a combination of more of silicon oxide (SiO₂), aluminum oxide (Al₂O₃), zirconium oxide (ZrO₂), hafnium oxide (HfO₂), titanium oxide (TiO₂), tantalum oxide (Ta₂O₅), barium strontium titanate (BST), strontium titanate (STO), and lead zirconate titanate (PZT). In an example embodiment of the present disclosure, the first electrode layer 31, the second electrode layer 33, and/or other electrode layers (e.g., the third electrode layer 35 and the fourth electrode layer 37) each are made of titanium nitride, and the first capacitor dielectric layer 32 and/or other capacitor dielectric layers (e.g., the second capacitor dielectric layer 34 and the third capacitor dielectric layer 36) each are made of a high-K (high-K) material.

Each of the lead-out electrode layers 2 is located in the interposer 1, and is electrically connected to one first electrode layer 31 and/or one second electrode layer 33, and extends in the preset direction.

In example Embodiment 1 of the present disclosure, specifically, as shown in FIG. 5 or FIG. 6, the lead-out electrode layers 2 further extend in a depth direction of the trenches 30 in the interposer 1, and each of the lead-out electrode layers 2 includes only a first lead-out electrode layer 21. The first lead-out electrode layer 21 is located between adjacent trenches 30 and is electrically connected to the first electrode layer 31.

In example Embodiment 2 of the present disclosure, specifically, as shown in FIG. 8 or FIG. 9, the lead-out electrode layers 2 further extend in a depth direction of the trenches 30 in the interposer 1, and each of the lead-out electrode layers 2 includes a first lead-out electrode layer 21 and a second lead-out electrode layer 22. The first lead-out electrode layer 21 is located between adjacent trenches 30 and is electrically connected to the first electrode layer 31, and the second lead-out electrode layer 22 is located in one trench 30 and is electrically connected to the second electrode layer 33.

In example Embodiment 3 of the present disclosure, specifically, as shown in FIG. 12 or FIG. 13, the lead-out electrode layers 2 further extend in a depth direction of the trenches 30 in the interposer 1, and each of the lead-out electrode layers 2 includes a first lead-out electrode layer 21, a second lead-out electrode layer 22, a third lead-out electrode layer 23, and a fourth lead-out electrode layer 24. The first lead-out electrode layer 21 is located between adjacent trenches 30 and is electrically connected to the first electrode layer 31, and the second lead-out electrode layer 22 is located on an outer side of the trench 30 at an outermost side of the trench array 300 and is electrically connected to the second electrode layer 33. The third lead-out electrode layer 23 is located on an outer side of the trench 30 at another outermost side of the trench array 300 and is electrically connected to the third electrode layer 35, and the fourth lead-out electrode layer 24 is located in one trench 30 and is electrically connected to the fourth electrode layer 37. It should be noted that “first outermost side” and “second outermost side” herein are two opposite sides of the trench array 300, and directions of the two opposite sides are perpendicular to the preset direction. The outer side of the trench 30 is a side, which is away from an adjacent trench 30, of the trench 30 located at the first outermost side or the second outermost side.

In example Embodiment 4 of the present disclosure, specifically, as shown in FIG. 16, each of the lead-out electrode layers 2 is located only in a region of one trench 30 close to a bottom of the trench 30, and each of the lead-out electrode layers 2 includes a first lead-out electrode layer 21, a second lead-out electrode layer 22, and a third lead-out electrode layer 23. The first lead-out electrode layer 21 covers an upper surface of a portion, located at the bottom of the trench 30, of the second electrode layer 33 and is electrically connected to the second electrode layer 33, and the second lead-out electrode layer 22 covers an upper surface of a portion, located at the bottom of the trench 30, of the third electrode layer 35 and is electrically connected to the third electrode layer 35. The third lead-out electrode layer 23 covers an upper surface of a portion, located at the bottom of the trench 30, of the fourth electrode layer 37 and is electrically connected to the fourth electrode layer 37.

In example Embodiment 5 of the present disclosure, specifically, as shown in FIG. 18, each of the lead-out electrode layers 2 is located only in a region of one trench 30 close to a bottom of the trench 30, and each of the lead-out electrode layers 2 includes a first lead-out electrode layer 21, a second lead-out electrode layer 22, a third lead-out electrode layer 23, and a fourth lead-out electrode layer 24. The first lead-out electrode layer 21 covers an upper surface of a portion, located at the bottom of the trench 30, of the first electrode layer 31 and is electrically connected to the first electrode layer 31, and the second lead-out electrode layer 22 covers an upper surface of a portion, located at the bottom of the trench 30, of the second electrode layer 33 and is electrically connected to the second electrode layer 33. The third lead-out electrode layer 23 covers an upper surface of a portion, located at the bottom of the trench 30, of the third electrode layer 35 and is electrically connected to the third electrode layer 35, and the fourth lead-out electrode layer 24 covers an upper surface of a portion, located at the bottom of the trench 30, of the fourth electrode layer 37 and is electrically connected to the fourth electrode layer 37.

In the above-mentioned multiple embodiments, the first lead-out electrode layer 21, the second lead-out electrode layer 22, the third lead-out electrode layer 23, and/or the fourth lead-out electrode layer 24 may be made of one or a combination of more of tungsten (W), molybdenum (Mo), ruthenium (Ru), tantalum (Ta), platinum (Pt), copper (Cu), and/or nitrides thereof. In an example embodiment of the present disclosure, the first lead-out electrode layer 21, the second lead-out electrode layer 22, the third lead-out electrode layer 23, and/or the fourth lead-out electrode layer 24 is made of copper. In Embodiments 3, 4, and 5, the capacitor 3 includes more than two electrode layers, and adjacent electrode layers are separated by a capacitor dielectric layer to form multiple sub-capacitors sequentially connected in series. A total resistance may be regarded as a parallel resistance of the sub-capacitors. According to a calculation formula of the parallel resistance, the total resistance of the capacitor 3 is less than that of any of the sub-capacitors. With the increase of the number of electrode layers, the total resistance of the capacitor 3 becomes smaller, thereby reducing a delay effect of a capacitor device to a certain extent and enabling the capacitor to be charged or discharged quickly.

In some embodiments, the semiconductor structure further includes: contact members 5 and an interlayer dielectric layer 4. The interlayer dielectric layer 4 covers top surfaces of the capacitors 3, and the contact members 5 penetrate through the interlayer dielectric layer 4 to be electrically connected to one lead-out electrode layer 2 and/or one first electrode layer 31 and one second electrode layer 33. Specifically, in some embodiments, the contact members 5 may be in one-to-one corresponding contact with the lead-out electrode layers 2 for electrical connection, and the contact members 5 may alternatively be in direct contact and electrical connection with the first electrode layer 31, the second electrode layer 33, and/or other electrode layers without the lead-out electrode layer 2. Specifically, a window is formed on a surface of the capacitor 3. The window opens all or part of film layers of the capacitor 3 to expose the top surface of the lead-out electrode layer 2 and/or part of top surfaces of the first electrode layer 31, the second electrode layer 33 or other electrode layers, and one contact member 5 is in direct contact with the lead-out electrode layer 2 and/or the first electrode layer 31, the second electrode layer 33, or other electrode layers through the window.

In some embodiments, areas where the lead-out electrode layer 2 and/or the first electrode layer 31, the second electrode layer 33, or other electrode layers are in contact with corresponding contact members 5 are located in an area in which the trench array 300 is located. Specifically, for example, in FIG. 5, areas where the first lead-out electrode layer 21 and the second electrode layer 33 are in contact with corresponding contact members 5 are located in an area in which the trench array 300 is located. For another example, in FIG. 8, areas where the first lead-out electrode layer 21 and the second lead-out electrode layer 22 are in contact with corresponding contact members 5 are located in an area in which the trench array 300 is located.

In some other embodiments, areas where the lead-out electrode layers 2 and/or the first electrode layer 31, the second electrode layer 33, or other electrode layers are in contact with corresponding contact members 5 are located outside the trench array 300, and the corresponding lead-out electrode layers 2 extend beyond an area in which the trench array 300 is located. Specifically, for example, in FIG. 16, areas where the first electrode layer 31, the first lead-out electrode layer 21, the second lead-out electrode layer 22, and the third lead-out electrode layer 23 are in contact with corresponding contact members 5 are located outside an area in which the trench array 300 is located. For another example, in FIG. 18, areas where the first lead-out electrode layer 21, the second lead-out electrode layer 22, the third lead-out electrode layer 23, and the fourth lead-out electrode layer 24 are in contact with corresponding contact members 5 are located outside an area in which the trench array 300 is located.

In another embodiment, areas where part of the lead-out electrode layers 2 or the electrode layers are in contact with corresponding contact members 5 are located in an area in which the trench array 300 is located, while areas where another part of the lead-out electrode layers 2 or the electrode layers are in contact with corresponding contact members 5 are located outside the area in which the trench array 300 is located. Specifically, for example, in FIG. 6, an area where the first lead-out electrode layer 21 is in contact with a corresponding contact member 5 is located outside an area in which the trench array 300 is located, while an area where the second electrode layer 33 is in contact with a corresponding contact member 5 is located in the area in which the trench array 300 is located. For another example, in FIG. 9, an area where the first lead-out electrode layer 21 is in contact with a corresponding contact member 5 is located outside an area in which the trench array 300 is located, while an area where the second lead-out electrode layer 22 is in contact with a corresponding contact member 5 is located in the area in which the trench array 300 is located. For another example, areas where the second lead-out electrode layer 22 and the third lead-out electrode layer 23 in FIG. 12 and the first lead-out electrode layer 21, the second lead-out electrode layer 22, and the third lead-out electrode layer 23 in FIG. 13 are in contact with corresponding contact members 5 are located outside an area in which the trench array 300 is located, while areas where the first lead-out electrode layer 21 and the fourth lead-out electrode layer 24 in FIG. 12 and the fourth lead-out electrode layer 24 in FIG. 13 are in contact with corresponding contact members 5 are located in an area in which the trench array 300 is located.

In some embodiments, as shown in FIG. 16 or FIG. 18, the structure in which the contact members 5 are in contact with the lead-out electrode layers 2 extending out of an area in which the trench array 300 is located has a stepped shape, to facilitate the contact between the lead-out electrode layers 2 and the corresponding contact members 5. Compared with the area of the trench array 300 in which adjacent trenches 30 are densely arranged, an area outside the trench array 300 is relatively empty, which helps avoid short circuit and other problems between adjacent contact members 5 caused by a limited space position.

In some embodiments, the contact members 5 may be made of one or a combination of more of tungsten (W), molybdenum (Mo), ruthenium (Ru), tantalum (Ta), platinum (Pt), copper (Cu), and/or nitrides thereof. In an example embodiment of the present disclosure, the contact members 5 are made of tungsten. In some embodiments, the interlayer dielectric layer 4 may be made of at least one or any combination of the following materials: silicon oxide, silicon nitride, silicon oxynitride, silicon carbide, silicon carbonitride, and silicon oxycarbonitride. In an example embodiment of the present disclosure, the interlayer dielectric layer 4 is made of silicon oxide.

In some embodiments, the semiconductor structure further includes: a bottom dielectric layer 6. The bottom dielectric layer 6 is located below the capacitors 3 and covers at least bottoms and sidewalls of the plurality of trenches 30. The bottom dielectric layer 6 is located between the interposer 1 and the first electrode layer 31. In some embodiments, the bottom dielectric layer 6 is also located between the interposer 1 and the first lead-out electrode layer 21, and the first electrode layer 31 (and the first lead-out electrode layer 21) covers a surface of the bottom dielectric layer 6. A function of the bottom dielectric layer 6 is to prevent the interposer 1 from interfering with the potential of the first electrode layer 31 and prevent impurities in the interposer 1 from polluting a material of the first electrode layer 31, which otherwise affects working performance of the capacitor 3. In some embodiments, the bottom dielectric layer 6 may be made of at least one or any combination of the following materials: silicon oxide, silicon nitride, silicon oxynitride, silicon carbide, silicon carbonitride, and silicon oxycarbonitride. In an example embodiment of the present disclosure, the interlayer dielectric layer 6 is made of silicon oxide. In another embodiment, when the purity of a silicon-based material in the interposer 1 is high, the semiconductor structure may have no bottom dielectric layer 6, and the first electrode layer 31 may be in direct contact with an inner surface of each of the trenches 30 in the interposer 1, or even the first electrode layer 31 may be directly formed by doping the inner surface of the trench 30.

In some embodiments, multiple trenches 30 extending in the same preset direction are parallel to each other and are arranged at intervals in a direction perpendicular to the preset direction. Specifically, multiple trenches 30 extending in the X direction or a reverse direction thereof are arranged at intervals in the Y direction or a reverse direction thereof. In some embodiments, spacings between adjacent trenches 30 are equal.

In an example embodiment of the present disclosure, referring to FIG. 20, the interposer 1 further includes a first region 11 and a second region 12 that are adjacently arranged. In the first region 11, a preset direction in which the trenches 30 extend is a first direction, which is the same as or opposite to the X direction, and in the second region 12, a preset direction in which the trenches 30 extend is a second direction, which is the same as or opposite to the Y direction. In some embodiments, the interposer 1 further includes a third region 13 and a fourth region 14 that are adjacently arranged. The third region 13 has the same preset direction as the first region 11 and the fourth region 14 has the same preset direction as the second region 12. The third region 13 is further arranged adjacent to the second region 12 in the Y direction, and the fourth region 14 is further arranged adjacent to the first region 11 in the Y direction. In some other embodiments, the interposer 1 may include more regions, but preset directions in which the trenches 30 extend in the adjacently arranged regions need to be perpendicular to each other. The preset directions in different regions are perpendicular to each other, which can effectively solve stress and other problems in the interposer 1.

In the semiconductor structure according to the present disclosure, the interposer has the trench array including the multiple trenches, and the capacitors are located at least in the trenches. This effectively increases a capacitor area and increases the capacitor capacity, thereby improving performance of the capacitors. The capacitors in the trenches are connected in series in multiple stages, a resistance thereof is a parallel resistance, which is reduced, and a delay effect of a circuit is reduced, thereby increasing a charging/discharging speed of the capacitors. In addition, the interposer is further provided with lead-out electrode layers made of a material with higher conductivity, and the lead-out electrode layers also extend in the preset direction, so that an on-resistance is greatly reduced. In addition, the lead-out electrode layers are connected to the contact members or the first electrode layers, the second electrode layers, and/or other electrode layers in the capacitors in a one-to-one correspondence, which can further meet requirements for fast charging and discharging of the capacitors. The lead-out electrode layers extend out of the trench array, and areas of the contact members in contact with lead-out electrode layers are located outside the trench array, so as to avoid the problem such as short circuit between adjacent contact members caused by a space limitation on the trenches (capacitors) arranged in high density in the trench array, and improve reliability of the device. Preset directions in which trenches extend in adjacent regions in the interposer are perpendicular to each other, which effectively solves stress and other problems in the interposer. To sum up, the semiconductor structure according to the present disclosure has the advantages of large capacity, fast charge and discharge, high integration, and high reliability, thereby greatly improving device performance of the DTC structure. An arrangement mode thereof has a good improvement effect against the stress problem in the interposer.

Based on the above-mentioned semiconductor structure, the present disclosure further provides a manufacturing method for a semiconductor structure, including the steps as follows. An interposer 1 is provided. As shown in FIG. 1, FIG. 1(a) is a top view obtained by facing the interposer 1 in a reverse direction of the Z direction, and FIG. 1(b) is a schematic cross-sectional view taken along a dashed line A-A′ of FIG. 1(a). A cross-section taken along the dashed line A-A′ is perpendicular to the top surface of the interposer 1.

In an example embodiment of the present disclosure, an Si interposer is adopted as the interposer 1. The Si interposer may be made of at least one of the following materials:
silicon, germanium, silicon on insulator (SOI), stacked silicon on insulator (SSOI), stacked silicon-germanium on insulator (S-SiGeOI), silicon-germanium on insulator (SiGeOI), germanium on insulator (GeOI), and other semiconductor materials or a combination of III-V materials and organic materials.

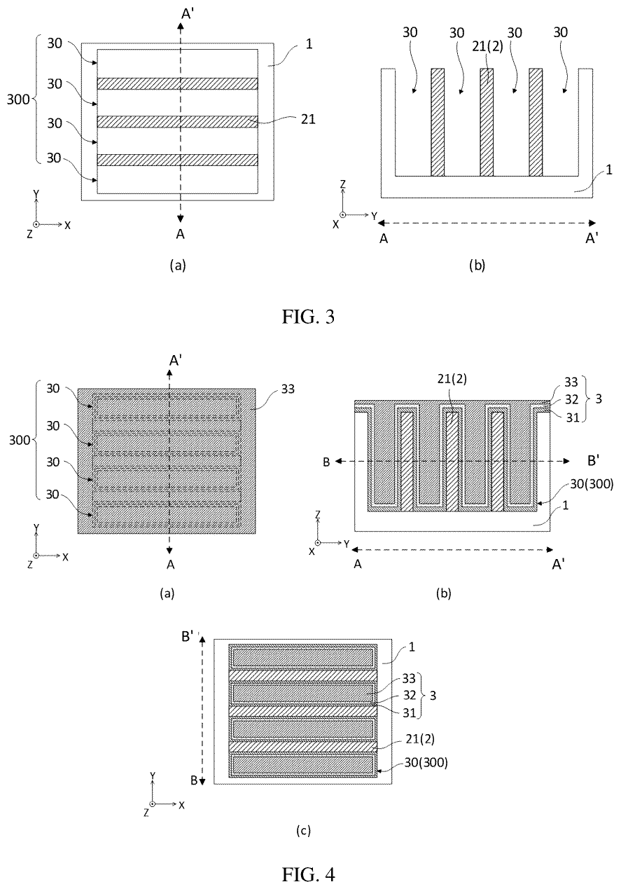

Then, lead-out electrode layers 2 and a trench array 300 including multiple trenches 30 extending from a top surface of the interposer 1 toward an interior of the interposer 1 are formed in the interposer 1. In example Embodiment 1 of the present disclosure, each of the lead-out electrode layers 2 includes only a first lead-out electrode layer 21. Referring to FIG. 2 and FIG. 3, first, the first lead-out electrode layers 21 extending in a preset direction are formed in the interposer 1. Then, trenches 30 are formed on both sides of the first lead-out electrode layer 21, and multiple trenches 30 extend in the preset direction and are arranged at intervals perpendicular to the preset direction to form a trench array 300. The first lead-out electrode layers 21 and the trenches 30 extend in a depth direction from the top surface of the interposer 1 toward the interior of the interposer 1. FIG. 2(a)/FIG. 3(a) is a top view of the interposer 1 faced in a reverse direction of the Z direction, and FIG. 2(b)/FIG. 3(b) is a schematic cross-sectional view taken along a dashed line A-A′ of FIG. 2(a)/FIG. 3(a). A cross-section taken along the dashed line A-A′ is perpendicular to the top surface of the interposer 1. Specifically, as shown in FIG. 2, first, electrode trenches (not shown) with a certain depth are formed through etching from the surface of the interposer 1 toward the interior of the interposer 1, and each of the electrode trenches is filled with a lead-out electrode material to form a first lead-out electrode layer 21, and the first lead-out electrode layer 21 extends in a depth direction toward the interior of the interposer 1 and perpendicular to a plane on which the top surface of the interposer 1 is located. The depth direction is opposite to the Z direction in the figure. Parallel to the plane on which the top surface of the interposer 1 is located, the first lead-out electrode layer 21 extends in a preset direction, and in FIG. 2, the preset direction is the X direction or a reverse direction thereof. Then, as shown in FIG. 3, on both sides of the first lead-out electrode layer 21, trenches 30 with a certain depth are formed through etching from the surface of the interposer 1 toward the interior of the interposer 1, and the trenches 30 also extend in the preset direction. In some embodiments, the trenches 30 and the first lead-out electrode layer 21 also have the same depth dimension in the depth direction and/or the same length dimension in the preset direction. In another embodiment, each of the trenches 30 has a larger or smaller depth dimension in the depth direction and/or a larger or smaller length dimension in the preset direction than the first lead-out electrode layer 21. In some embodiments, a schematic cross-sectional view of each of the trenches 30 in the depth direction is rectangular, that is, the opening dimension of the trench 30 is basically the same as the bottom dimension thereof. In some other embodiments, a schematic cross-sectional view of each of the trenches 30 is trapezoidal. For example, the opening dimension of the trench 30 is larger than the bottom dimension thereof, or the bottom dimension of the trench 30 is larger than the opening dimension thereof.

In some embodiments, the surface of the interposer 1 can be etched by using a photolithography process to form electrode trenches (not shown) or trenches 30. Specifically, a photoresist mask layer may be formed on the surface of the interposer 1, and patterns of the electrode trenches (not shown) or the trenches 30 may be formed in the photoresist mask layer through exposure and development. Then dry etching may be performed to etch the interposer 1 along the patterns to form the electrode trenches (not shown) or the trenches 30. In some embodiments, before the photoresist mask layer is coated, the method further includes the steps as follows. An antireflection layer and a hard mask layer (not shown) are formed on the surface of the interposer 1, and are removed when the electrode trenches (not shown) or the trenches 30 are formed. In some embodiments, the trenches 30 may be formed on both sides of the first lead-out electrode layer 21 by self-aligned etching after the first lead-out electrode layer 21 is formed, that is, the trenches are formed through selective etching by adjusting a high selectivity ratio of materials of the first lead-out electrode layer 21 and the interposer 1.

Then, a capacitor 3 including at least a first electrode layer 31, a first capacitor dielectric layer 32, and a second electrode layer 33 that are sequentially stacked is formed in each of the trenches 30. The first capacitor dielectric layer 32 covers a surface of the first electrode layer 31, and the second electrode layer 33 covers a surface of the first capacitor dielectric layer 32. As shown in FIG. 4, FIG. 4(a) is a top view obtained by facing the interposer 1 in a reverse direction of the Z direction. FIG. 4(b) is a schematic cross-sectional view taken along a dashed line A-A′ of FIG. 4(a). FIG. 4(c) is a schematic cross-sectional view taken along a dashed line B-B′ of FIG. 4(b). The cross-section taken along the dashed line A-A′ is perpendicular to the top surface of the interposer 1, and the cross-section taken along the dashed line B-B′ is parallel to the top surface of the interposer 1.

In some embodiments, the first lead-out electrode layer 21 extends in the depth direction of the trenches 30 in the interposer 1, and the first electrode layer 31 covers a surface of the first lead-out electrode layer 21, and is in direct contact and electrical connection with the first lead-out electrode layer 21. As shown in FIG. 5(b), the capacitors 3 located in the trenches 30 each are arranged at an interval with the first lead-out electrode layer 21 in a direction perpendicular to the preset direction. In FIG. 5, the preset direction is the X direction or the reverse direction thereof, and the direction perpendicular to the preset direction is the Y direction or the reverse direction thereof. The first electrode layer 31 of the capacitor 3 further covers an inner wall and a bottom surface of one trench 30. In some embodiments, the capacitors 3 further extend to cover the top surface of the interposer 1.

Then, after the capacitors 3 are formed, an interlayer dielectric layer 4 and contact members 5 are formed on the interposer 1. Specifically, the interlayer dielectric layer 4 is first formed on the interposer 1 to cover at least the top surfaces of the capacitors 3, and then the contact members 5 are formed, each of which penetrates through the interlayer dielectric layer 4, so as to be in contact and electrical connection with one lead-out electrode layer 2 or one electrode layer (e.g., the first electrode layer, the second electrode layer, or other electrode layers) in the capacitor 3.

In example Embodiment 1 of the present disclosure, as shown in FIG. 5 or FIG. 6, the contact members 5 penetrate through the interlayer dielectric layer 4, to be respectively in contact and electrical connection with the second electrode layers 33 of the capacitors 3 in the trenches 30, and are in direct contact and electrical connection with first lead-out electrode layers 21 between adjacent trenches 30. Before the interlayer dielectric layer 4 is formed to cover the top surfaces of the capacitors 3, the method further includes the steps as follows. Windows are formed in film layers of the capacitors 3 located at the tops of the first lead-out electrode layers 21, to expose the tops of the first lead-out electrode layers 21, the windows are filled with the interlayer dielectric layer 4 formed subsequently, and the contact members 5 penetrate through the interlayer dielectric layer 4 through the windows to be in contact with the tops of the first lead-out electrode layers 21. In some embodiments, as shown in FIG. 5, areas where the first lead-out electrode layers 21 and the second electrode layers 33 are in contact with corresponding contact members 5 are located in an area in which the trench array 300 is located. In some other embodiments, as shown in FIG. 6, areas where the second electrode layers 33 are in contact with corresponding contact members 5 are located in an area in which the trench array 300 is located, and areas where the first lead-out electrode layers 21 are in contact with corresponding contact members 5 are located outside the area in which the trench array 300 is located. Correspondingly, the first lead-out electrode layers 21 also extend to the outside of the trench array 300.

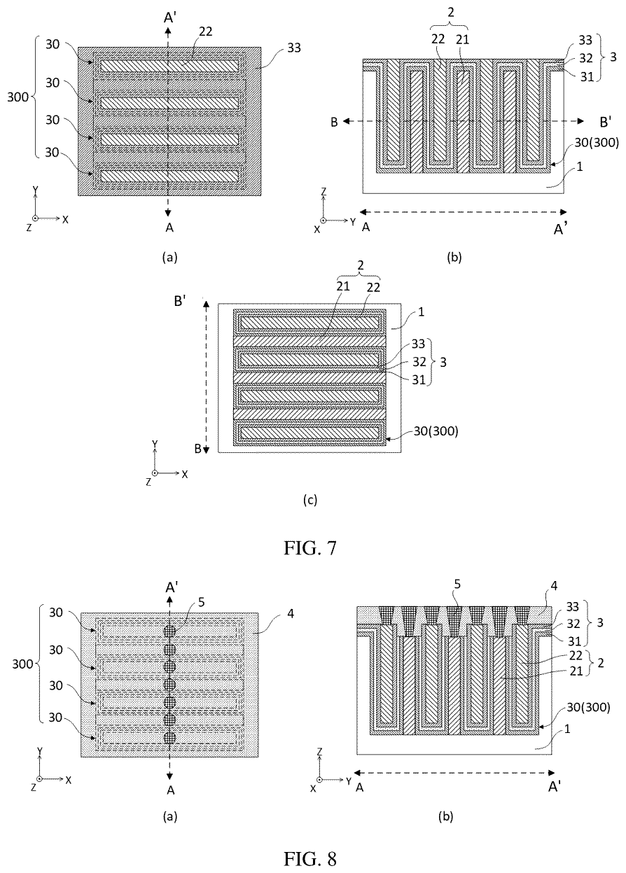

In example Embodiment 2 of the present disclosure, as shown in FIG. 7, before the interlayer dielectric layer 4 and the contact members 5 are formed on the interposer 1, the method further includes the steps as follows. After the second electrode layers 33 are formed, the trenches 30 are not filled with the capacitors 3, then the second lead-out electrode layers 22 are formed in the trenches 30 to cover surfaces of the second electrode layers 33 and fill the trenches 30, and the second lead-out electrode layers 22 are in direct contact and electrical connection with the second electrode layers 33. Then, as shown in FIG. 8 or FIG. 9, the contact members 5 penetrate through the interlayer dielectric layer 4, are respectively in direct contact and electrical connection with the second lead-out electrode layers 22 in the trenches 30, and are in direct contact and electrical connection with first lead-out electrode layers 21 between adjacent trenches 30. Before the interlayer dielectric layer 4 is formed to cover the top surfaces of the capacitors 3, the method further includes the steps as follows. Windows are formed in film layers of the capacitors 3 located at the tops of the first lead-out electrode layers 21, to expose the tops of the first lead-out electrode layers 21, the windows are filled with the interlayer dielectric layer 4 formed subsequently, and the contact members 5 penetrate through the interlayer dielectric layer 4 through the windows to be in contact with the tops of the first lead-out electrode layers 21. In some embodiments, as shown in FIG. 8, areas where the first lead-out electrode layers 21 and the second lead-out electrode layers 22 are in contact with corresponding contact members 5 are located in an area in which the trench array 300 is located. In some other embodiments, as shown in FIG. 9, areas where the second lead-out electrode layers 22 are in contact with corresponding contact members 5 are located in an area in which the trench array 300 is located, and areas where the first lead-out electrode layers 21 are in contact with corresponding contact members 5 are located outside the area in which the trench array 300 is located. Correspondingly, the first lead-out electrode layers 21 also extend to the outside of the trench array 300.

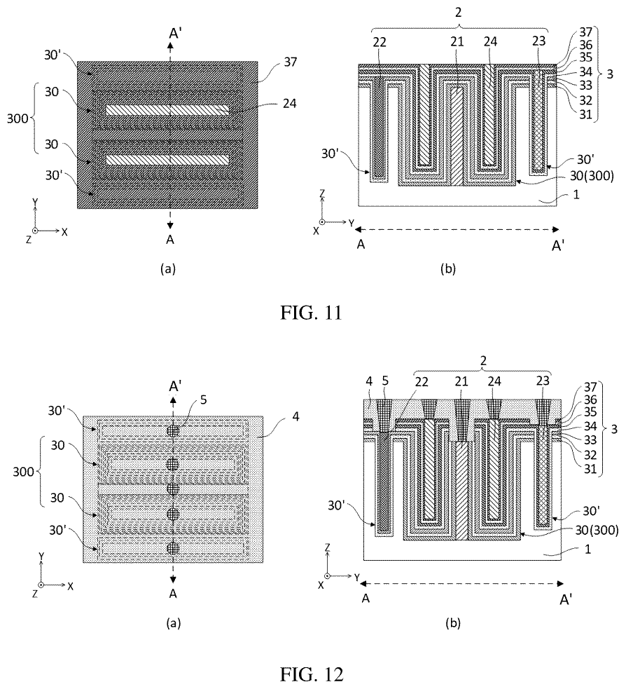

In example Embodiment 3 of the present disclosure, as shown in FIG. 10 and FIG. 11, before trenches 30 are formed, a first lead-out electrode layer 21 is formed in an interposer 1, subsequently the trenches 30 are formed on both sides of the first lead-out electrode layer 21, and the first lead-out electrode layer 21 is located between the adjacent trenches 30. A first electrode layer 31 formed subsequently covers a surface of the first lead-out electrode layer 21 and is in contact and electrical connection with the first lead-out electrode layer 21. After the first lead-out electrode layer 21 and the trenches 30 are formed, capacitors 3 are formed in the trenches 30. In addition to including the first electrode layer 31, a first capacitor dielectric layer 32, and a second electrode layer 33, the capacitor 3 further includes a second capacitor dielectric layer 34, a third electrode layer 35, a third capacitor dielectric layer 36, and a fourth electrode layer 37 that are sequentially stacked. The second capacitor dielectric layer 34 covers a surface of the second electrode layer 33, and the third electrode layer 35 covers a surface of the second capacitor dielectric layer 34. The third capacitor dielectric layer 36 covers a surface of the third electrode layer 35, and the fourth electrode layer 37 covers a surface of the third capacitor dielectric layer 36. In addition to including the first lead-out electrode layer 21 and a second lead-out electrode layer 22, each of the lead-out electrode layers 2 further includes a third lead-out electrode layer 23 and a fourth lead-out electrode layer 24. Specifically, after the second electrode layer 33 is formed and before the second capacitor dielectric layer 34 is formed, the second lead-out electrode layer 22 is formed, and the second lead-out electrode layer 22 is located on an outer side of the trench 30 at a first outermost side of the trench array 300 and is electrically connected to the second electrode layer 33; after the third electrode layer 35 is formed and before the third capacitor dielectric layer 36 is formed, the third lead-out electrode layer 23 is formed, and the third lead-out electrode layer 23 is located on an outer side of the trench 30 at a second outermost side of the trench array 300 and is electrically connected to the third electrode layer 35; and after the fourth electrode layer 37 is formed, the fourth lead-out electrode layer 24 is formed in one trench 30 to fill the trench 30 and be electrically connected to the fourth electrode layer 37. More specifically, after the first electrode layer 31 is formed and before the first capacitor dielectric layer 32 is formed, a lead-out trench 30′ is formed on the outer side of the trench 30 at the first outermost side of the trench array 300, then a first capacitor dielectric layer 32 and a second electrode layer 33 that are sequentially stacked are formed in the lead-out trench 30′, and the second lead-out electrode layer 22 covers the surface of the second electrode layer 33 and fills the lead-out trench 30′. After the second electrode layer 33 is formed and before the second capacitor dielectric layer 34 is formed, another lead-out trench 30′ is formed on the outer side of the trench 30 at the second outermost side of the trench array 300, then a second capacitor dielectric layer 34 and a third electrode layer 35 that are sequentially stacked are formed in the lead-out trench 30′, and the third lead-out electrode layer 23 covers the surface of the third electrode layer 35 and fills the lead-out trench 30′. It should be noted that “first outermost side” and “second outermost side” herein are two opposite sides of the trench array 300, and directions of the two opposite sides are perpendicular to the preset direction. The outer side of the trench 30 is a side, which is away from an adjacent trench 30, of the trench 30 located at the first outermost side or the second outermost side.

Then, as shown in FIG. 12 or FIG. 13, an interlayer dielectric layer 4 and contact members 5 are formed on the interposer 1. The interlayer dielectric layer 4 covers at least the top surfaces of the capacitors 3, and the contact members 5 penetrate through the interlayer dielectric layer 4, are respectively in direct contact and electrical connection with the first lead-out electrode layer 21 between adjacent trenches 30, are in direct contact and electrical connection with the second lead-out electrode layers 22 and the third lead-out electrode layers 23 in the lead-out trenches 30′, and are in direct contact and electrical connection with the fourth lead-out electrode layers 24 in the trenches 30. Before the interlayer dielectric layer 4 is formed to cover the top surfaces of the capacitors 3, the method further includes the steps as follows. Windows are formed in film layers of the capacitors 3 located at the tops of the first lead-out electrode layer 21, the second lead-out electrode layer 22, and the third lead-out electrode layer 23, to expose the tops of the first lead-out electrode layer 21, the second lead-out electrode layer 22, and the third lead-out electrode layer 23, the windows are filled with the interlayer dielectric layer 4 formed subsequently, and the contact members 5 penetrate through the interlayer dielectric layer 4 through the windows to be respectively in contact with the tops of the first lead-out electrode layer 21, the second lead-out electrode layer 22, and the third lead-out electrode layer 23. In some embodiments, as shown in FIG. 12, areas where the first lead-out electrode layer 21 and the fourth lead-out electrode layer 24 are in contact with corresponding contact members 5 are located in an area in which the trench array 300 is located, and areas where the second lead-out electrode layer 22 and the third lead-out electrode layer 23 are in contact with corresponding contact members 5 are located outside the area in which the trench array 300 is located (located in the lead-out trench 30′ at the outer side of the trench array 300). In some other embodiments, as shown in FIG. 13, an area where only the fourth lead-out electrode layer 24 is in contact with a corresponding contact member 5 is located in an area in which the trench array 300 is located, and areas where the first lead-out electrode layer 21, the second lead-out electrode layer 22, and the third lead-out electrode layer 23 are in contact with corresponding contact members 5 are located outside the area in which the trench array 300 is located. Correspondingly, the first lead-out electrode layer 21, the second lead-out electrode layer 22, and the third lead-out electrode layer 23 also extend to the outside of the trench array 300.

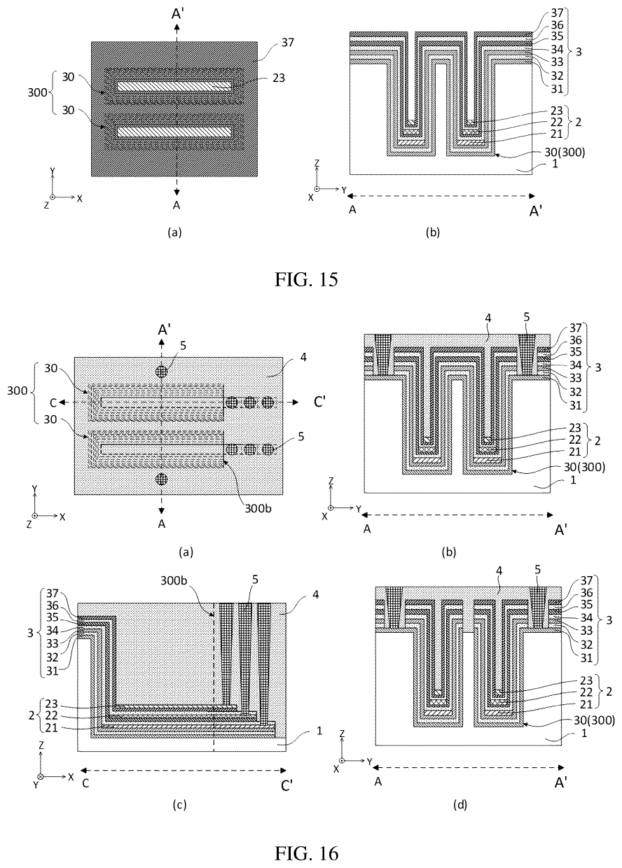

In example Embodiment 4 of the present disclosure, as shown in FIG. 14 and FIG. 15, trenches 30 are formed in an interposer 1 first, and then capacitors 3 each including a first electrode layer 31, a first capacitor dielectric layer 32, a second electrode layer 33, a second capacitor dielectric layer 34, a third electrode layer 35, a third capacitor dielectric layer 36, and a fourth electrode layer 37 that are sequentially stacked are formed in the interposer 1. The first capacitor dielectric layer 32 covers a surface of the first electrode layer 31, and the second electrode layer 33 covers a surface of the first capacitor dielectric layer 32. The second capacitor dielectric layer 34 covers a surface of the second electrode layer 33, and the third electrode layer 35 covers a surface of the second capacitor dielectric layer 34. The third capacitor dielectric layer 36 covers a surface of the third electrode layer 35, and the fourth electrode layer 37 covers a surface of the third capacitor dielectric layer 36. After the second electrode layer 33 is formed and before the second capacitor dielectric layer 34 is formed, a first lead-out electrode layer 21 is formed in one trench 30, and the first lead-out electrode layer 21 covers only an upper surface of a portion, located at the bottom of the trench 30, of the second electrode layer 33 and is in direct contact and electrical connection with the second electrode layer 33. After the third electrode layer 35 is formed and before the third capacitor dielectric layer 36 is formed, a second lead-out electrode layer 22 is formed in the trench 30, and the second lead-out electrode layer 22 covers only an upper surface of a portion, located at the bottom of the trench 30, of the third electrode layer 35 and is in direct contact and electrical connection with the third electrode layer 35. After the fourth electrode layer 37 is formed, a third lead-out electrode layer 23 is formed in the trench, covers only an upper surface of a portion, located at the bottom of the trench 30, of the fourth electrode layer 37 and is in direct contact and electrical connection with the fourth electrode layer 37.

Then, as shown in FIG. 16, an interlayer dielectric layer 4 and contact members 5 are formed on the interposer 1. The interlayer dielectric layer 4 covers at least the top surfaces of the capacitors 3, and the contact members 5 penetrate through the interlayer dielectric layer 4, to be respectively in direct contact and electrical connection with the first electrode layer 31, the first lead-out electrode layer 21, the second lead-out electrode layer 22, and the third lead-out electrode layer 23. Before the interlayer dielectric layer 4 is formed to cover the top surfaces of the capacitors 3, the method further includes the steps as follows. Windows are formed in film layers of the capacitors 3 located at the tops of the first electrode layers 31 extending to the top surface of the interposer 1, to expose part of the tops of the first electrode layers 31, and contact members 5 formed subsequently penetrate through the interlayer dielectric layer 4 through the windows to be in direct contact with the first electrode layers 31. One end of the trench array 300 is etched and trimmed to obtain a second boundary 300b of the trench array 300, including that the film layers of the capacitor 3 except the second boundary 300b are etched and removed to retain only part of the film layers of the capacitor 3 located at the bottom of the trench 30. The first lead-out electrode layer 21, the second lead-out electrode layer 22, and the third lead-out electrode layer 23 are stepped. As shown in FIG. 16(c), contact members 5 formed subsequently penetrate through the interlayer dielectric layer 4 to be respectively in direct contact, outside the trench array 300, with the first lead-out electrode layer 21, the second lead-out electrode layer 22, and the third lead-out electrode layer 23 that are stepped. In some embodiments, the contact members 5 further penetrate through the second capacitor dielectric layer 34 on the top surface of the first lead-out electrode layer 21 to be in contact and electrical connection with the first lead-out electrode layer 21, and penetrate through the third capacitor dielectric layer 36 on the top surface of the second lead-out electrode layer 22 to be in contact and electrical connection with the second lead-out electrode layer 22. In some embodiments, the film layers of the capacitors 3 on the top surface of the interposer 1 between adjacent trenches 30 are connected into a whole, as shown in FIG. 16(b). In some other embodiments, the film layers of the capacitors 3 on the top surface of the interposer 1 between adjacent trenches 30 are disconnected and isolated from each other, as shown in FIG. 16(d).

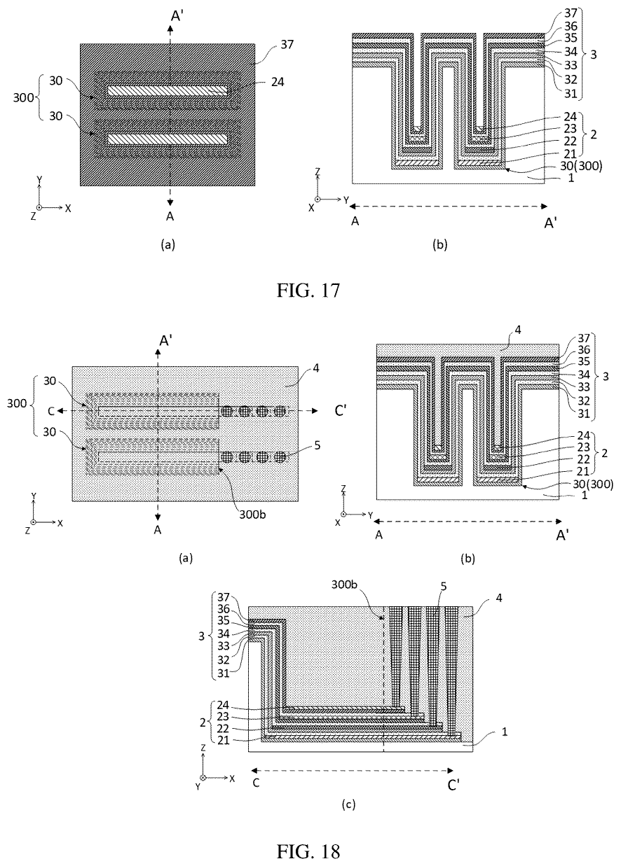

In example Embodiment 5 of the present disclosure, as shown in FIG. 14 and FIG. 17, trenches 30 are formed in an interposer 1 first, and then capacitors 3 each including a first electrode layer 31, a first capacitor dielectric layer 32, a second electrode layer 33, a second capacitor dielectric layer 34, a third electrode layer 35, a third capacitor dielectric layer 36, and a fourth electrode layer 37 that are sequentially stacked are formed in the interposer 1. The first capacitor dielectric layer 32 covers a surface of the first electrode layer 31, and the second electrode layer 33 covers a surface of the first capacitor dielectric layer 32. The second capacitor dielectric layer 34 covers a surface of the second electrode layer 33, and the third electrode layer 35 covers a surface of the second capacitor dielectric layer 34. The third capacitor dielectric layer 36 covers a surface of the third electrode layer 35, and the fourth electrode layer 37 covers a surface of the third capacitor dielectric layer 36. Before or after the first electrode layer 31 is formed, a first lead-out electrode layer 21 is formed in each of the trenches 30, and the first lead-out electrode layer 21 covers only a lower surface or an upper surface of a portion, located at the bottom of the trench 30, of the first electrode layer 31 and is in direct contact and electrical connection with the first electrode layer 31. After the second electrode layer 33 is formed and before the second capacitor dielectric layer 34 is formed, a second lead-out electrode layer 22 is formed in one trench 30, and the second lead-out electrode layer 22 covers only an upper surface of a portion, located at the bottom of the trench 30, of the second electrode layer 33 and is in direct contact and electrical connection with the second electrode layer 33. After the third electrode layer 35 is formed and before the third capacitor dielectric layer 36 is formed, a third lead-out electrode layer 23 is formed in the trench 30, and the third lead-out electrode layer 23 covers only an upper surface of a portion, located at the bottom of the trench 30, of the third electrode layer 35 and is in direct contact and electrical connection with the third electrode layer 35. After the fourth electrode layer 37 is formed, a fourth lead-out electrode layer 24 is formed in the trench, covers only an upper surface of a portion, located at the bottom of the trench 30, of the fourth electrode layer 37 and is in direct contact and electrical connection with the fourth electrode layer 37.

Then, as shown in FIG. 18, an interlayer dielectric layer 4 and contact members 5 are formed on the interposer 1. The interlayer dielectric layer 4 covers at least the top surfaces of the capacitors 3, and the contact members 5 penetrate through the interlayer dielectric layer 4, and are respectively in direct contact and electrical connection with the first lead-out electrode layer 21, the second lead-out electrode layer 22, the third lead-out electrode layer 23, and the fourth lead-out electrode layer 24. Before the interlayer dielectric layer 4 is formed to cover the top surfaces of the capacitors 3, the method further includes the steps as follows. One end of the trench array 300 is etched and trimmed to obtain a second boundary 300b of the trench array 300, including that the film layers of the capacitor 3 except the second boundary 300b are etched and removed to retain only part of the film layers of the capacitor 3 located at the bottom of the trench 30, where the first lead-out electrode layer 21, the second lead-out electrode layer 22, the third lead-out electrode layer 23, and the fourth lead-out electrode layer 24 are stepped. As shown in FIG. 18(c), the contact members 5 formed subsequently penetrate through the interlayer dielectric layer 4 to be in direct contact, outside the trench array 300, with the first lead-out electrode layer 21, the second lead-out electrode layer 22, the third lead-out electrode layer 23, and the fourth lead-out electrode layer 24 that are stepped. In some embodiments, the contact members 5 further penetrate through the first capacitor dielectric layer 33 on the top surface of the first lead-out electrode layer 21 to be in contact and electrical connection with the first lead-out electrode layer 21, penetrate through the second capacitor dielectric layer 34 on the top surface of the second lead-out electrode layer 22 to be in contact and electrical connection with the second lead-out electrode layer 22, and penetrate through the third capacitor dielectric layer 36 located on the top surface of the third lead-out electrode layer 23 to be in contact and electrical connection with the third lead-out electrode layer 23.

In example Embodiment 6 of the present disclosure, as shown in FIG. 19, a bottom dielectric layer 6 is formed in an interposer 1 first, and then trenches 30 are formed in the bottom dielectric layer 6. In some embodiments, a first lead-out electrode layer 21 is formed in the bottom dielectric layer 6 before the trenches 30 are formed, subsequently, capacitors 3 are formed in the trenches 30, and the bottom dielectric layer 6 is located at least between a first electrode layer 31 of the capacitor 3 and the interposer 1 (and between the first lead-out electrode layer 21 and the interposer 1).

In the above-mentioned multiple embodiments, the first electrode layer 31, the second electrode layer 33, the third electrode layer 35, and the fourth electrode layer 37 each may be made of at least one or a combination of more of doped silicon, titanium nitride (TiN), silicon doped titanium nitride (TiSiN), titanium (Ti), tungsten (W), tungsten nitride (WN), and silicon doped tungsten nitride (WSiN). The first capacitor dielectric layer 32, the second capacitor dielectric layer 34, and the third capacitor dielectric layer 36 each may be made of at least one or a combination of more of silicon oxide (SiO₂), aluminum oxide (Al₂O₃), zirconium oxide (ZrO₂), hafnium oxide (HfO₂), titanium oxide (TiO₂), tantalum oxide (Ta₂O₅), barium strontium titanate (BST), strontium titanate (STO), and lead zirconate titanate (PZT). The first lead-out electrode layer 21, the second lead-out electrode layer 22, the third lead-out electrode layer 23, and the fourth lead-out electrode layer 24 each may be made of one or a combination of more of tungsten (W), molybdenum (Mo), ruthenium (Ru), tantalum (Ta), platinum (Pt), copper (Cu), and/or nitrides thereof. The contact member 5 may be made of one or a combination of more of tungsten (W), molybdenum (Mo), ruthenium (Ru), tantalum (Ta), platinum (Pt), copper (Cu), and/or nitrides thereof. The interlayer dielectric layer 4 and the bottom dielectric layer 6 each may be made of at least one or any combination of the following materials: silicon oxide, silicon nitride, silicon oxynitride, silicon carbide, silicon carbonitride, and silicon oxycarbonitride. In an example embodiment of the present disclosure, the first electrode layer 31, the second electrode layer 33, the third electrode layer 35, and the fourth electrode layer 37 each are made of titanium nitride, the first capacitor dielectric layer 32, the second capacitor dielectric layer 34, and the third capacitor dielectric layer 36 each are made of a high-K material, the first lead-out electrode layer 21, the second lead-out electrode layer 22, the third lead-out electrode layer 23, and/or the fourth lead-out electrode layer 24 is made of copper, the contact member 5 is made of tungsten, and the interlayer dielectric layer 4 and the bottom dielectric layer 6 each are made of silicon oxide.

In some embodiments, a forming method for each electrode layer and each capacitor dielectric layer of the capacitor 3, each of the lead-out electrode layers 2, and each of the contact members 5 may be at least one of the following deposition methods: chemical vapor deposition (CVD), low-pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma assisted chemical vapor deposition (MPCVD), organometallic chemical vapor deposition (MOCVD), atomic layer deposition (ALD), physical vapor deposition (PVD), and sputtering. In some embodiments, a deposition method for the interlayer dielectric layer 4 and the bottom dielectric layer 6 may be at least one of the following deposition methods: chemical vapor deposition (CVD), low-pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma assisted chemical vapor deposition (MPCVD), organometallic chemical vapor deposition (MOCVD), atomic layer deposition (ALD), spin-on dielectric (SOD), in situ steam generation (ISSG), and a thermal oxide growth method.

In an example embodiment of the present disclosure, a semiconductor device is further provided, as shown in FIG. 21, which includes at least the semiconductor structure 101 according to any one of the aforementioned embodiments and chips 201 located on the semiconductor structure 101, where the chips 201 are electrically connected to the semiconductor structure 101 through solder ball bumps 401 and/or pads (not shown). In another embodiment, the chips 201 may alternatively be electrically connected to the semiconductor structure by wire bond (wire bond). In some embodiments, the interposer 1 in the semiconductor structure 101 further includes interconnection structures such as a redistribution layer (Re-distribution Layer, RDL) 1011 and through silicon vias (TSVs) 1012. In some embodiments, the chips 201 may be multiple memory chips stacked with each other, such as DRAM chips or NAND FLASH chips, and the chips 201 may be interconnected through bumps (bumps) or hybrid bonding (hybrid bonding) and through silicon vias (TSVs) 202. In some other embodiments, the chips 201 may alternatively be processor chips or image sensor chips. In some embodiments, the semiconductor device further includes a substrate 301 on which the semiconductor structure 101 is located, and the substrate 301 may also be electrically connected to the semiconductor structure 101 through solder ball bumps 402. In some embodiments, the substrate 301 may be a glass substrate, an organic substrate, or an insulating substrate, and solder ball bumps 403 are further included below the substrate 301 to connect a mainboard or another PCB.

It should be noted that the semiconductor structure or the semiconductor device in the embodiment of the present disclosure may be configured to manufacture a stacked packaging structure of memory chips, or may be configured to manufacture another device in which a capacitor structure needs to be manufactured in an interposer. There are not too many limitations herein.

Various semiconductor structures shown in this specific implementation can be used for an electronic device having a storage function. The electronic device may be a terminal device, e.g., a mobile phone, a tablet computer, or a smart band, or may be a personal computer (personal computer, PC), a server, a workstation, or the like. The storage function of the electronic device may be implemented by using the following memories: a dynamic random access memory (DRAM), a ferroelectric random access memory (FRAM), a phase change memory (PCM), a magnetic random access memory (MRAM), a resistive random access memory (RRAM), a flash memory (FLASH), some integrated storage products, or a system on chip.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A semiconductor structure, comprising:
an interposer, the interposer having a trench array comprising a plurality of trenches extending from a top surface of the interposer toward an interior of the interposer, and the plurality of trenches further extending in a preset direction parallel to the top surface of the interposer;
a capacitor located in the trenches, the capacitor comprising at least a first electrode layer, a first capacitor dielectric layer, and a second electrode layer being sequentially stacked, the first capacitor dielectric layer covering a surface of the first electrode layer, and the second electrode layer covering a surface of the first capacitor dielectric layer; and
lead-out electrode layers located in the interposer, the lead-out electrode layers being electrically connected to the first electrode layer and/or the second electrode layer and extending in the preset direction.

2. The semiconductor structure according to claim 1, wherein the lead-out electrode layers further extend in a depth direction of the trenches in the interposer, each of the lead-out electrode layers comprises only a first lead-out electrode layer, and the first lead-out electrode layer is located between adjacent trenches and is electrically connected to the first electrode layer.

3. The semiconductor structure according to claim 1, wherein the lead-out electrode layers further extend in a depth direction of the trenches in the interposer, each of the lead-out electrode layers comprises a first lead-out electrode layer and a second lead-out electrode layer, the first lead-out electrode layer is located between adjacent trenches and is electrically connected to the first electrode layer, and the second lead-out electrode layer is located in one trench and is electrically connected to the second electrode layer.

4. The semiconductor structure according to claim 1, wherein the capacitor further comprises a second capacitor dielectric layer, a third electrode layer, a third capacitor dielectric layer, and a fourth electrode layer being sequentially stacked, the second capacitor dielectric layer covers a surface of the second electrode layer, the third electrode layer covers a surface of the second capacitor dielectric layer, the third capacitor dielectric layer covers a surface of the third electrode layer, and the fourth electrode layer covers a surface of the third capacitor dielectric layer; and
the lead-out electrode layers further extend in a depth direction of the trenches in the interposer, each of the lead-out electrode layers comprises a first lead-out electrode layer, a second lead-out electrode layer, a third lead-out electrode layer, and a fourth lead-out electrode layer, the first lead-out electrode layer is located between adjacent trenches and is electrically connected to the first electrode layer, the second lead-out electrode layer is located on an outer side of the trench at a first outermost side of the trench array and is electrically connected to the second electrode layer, the third lead-out electrode layer is located on an outer side of the trench at a second outermost side of the trench array and is electrically connected to the third electrode layer, and the fourth lead-out electrode layer is located in one trench and is electrically connected to the fourth electrode layer,
wherein the first outermost side and the second outermost side are two opposite sides of the trench array, directions of the two opposite sides are perpendicular to the preset direction, and the outer side of the trench is a side, which is away from an adjacent trench, of the trench located at the first outermost side or the second outermost side.

5. The semiconductor structure according to claim 1, wherein the capacitor further comprises a second capacitor dielectric layer, a third electrode layer, a third capacitor dielectric layer, and a fourth electrode layer being sequentially stacked, the second capacitor dielectric layer covers a surface of the second electrode layer, the third electrode layer covers a surface of the second capacitor dielectric layer, the third capacitor dielectric layer covers a surface of the third electrode layer, and the fourth electrode layer covers a surface of the third capacitor dielectric layer; and
each of the lead-out electrode layers is located only in a region of one trench close to a bottom of the trench, each of the lead-out electrode layers comprises a first lead-out electrode layer, a second lead-out electrode layer, and a third lead-out electrode layer, the first lead-out electrode layer covers an upper surface of a portion, located at the bottom of the trench, of the second electrode layer and is electrically connected to the second electrode layer, the second lead-out electrode layer covers an upper surface of a portion, located at the bottom of the trench, of the third electrode layer and is electrically connected to the third electrode layer, and the third lead-out electrode layer covers an upper surface of a portion, located at the bottom of the trench, of the fourth electrode layer and is electrically connected to the fourth electrode layer.

6. The semiconductor structure according to claim 1, wherein the capacitor further comprises a second capacitor dielectric layer, a third electrode layer, a third capacitor dielectric layer, and a fourth electrode layer being sequentially stacked, the second capacitor dielectric layer covers a surface of the second electrode layer, the third electrode layer covers a surface of the second capacitor dielectric layer, the third capacitor dielectric layer covers a surface of the third electrode layer, and the fourth electrode layer covers a surface of the third capacitor dielectric layer; and
each of the lead-out electrode layers is located only in a region of one trench close to a bottom of the trench, each of the lead-out electrode layers comprises a first lead-out electrode layer, a second lead-out electrode layer, a third lead-out electrode layer, and a fourth lead-out electrode layer, the first lead-out electrode layer covers an upper surface of a portion, located at the bottom of the trench, of the first electrode layer and is electrically connected to the first electrode layer, the second lead-out electrode layer covers an upper surface of a portion, located at the bottom of the trench, of the second electrode layer and is electrically connected to the second electrode layer, the third lead-out electrode layer covers an upper surface of a portion, located at the bottom of the trench, of the third electrode layer and is electrically connected to the third electrode layer, and the fourth lead-out electrode layer covers an upper surface of a portion, located at the bottom of the trench, of the fourth electrode layer and is electrically connected to the fourth electrode layer.

7. The semiconductor structure according to claim 1, further comprising: contact members and an interlayer dielectric layer, the interlayer dielectric layer covering top surfaces of the capacitors, and the contact members penetrating through the interlayer dielectric layer to be electrically connected to one lead-out electrode layer and/or one first electrode layer and one second electrode layer.

8. The semiconductor structure according to claim 7, wherein an area where the contact members are electrically connected to the lead-out electrode layers and/or the first electrode layer and the second electrode layer, is located outside the trench array.

9. The semiconductor structure according to claim 1, further comprising: a bottom dielectric layer covering at least bottoms and sidewalls of the plurality of trenches, the bottom dielectric layer being located between the interposer and the first electrode layer, and the first electrode layer covering a surface of the bottom dielectric layer.

10. The semiconductor structure according to claim 1, wherein the interposer further comprises a first region and a second region being adjacently arranged, the preset direction is a first direction in the first region while the preset direction is a second direction in the second region, and the first direction and the second direction are perpendicular to each other; and
in the first region, the plurality of trenches extend in the first direction and are arranged at intervals in the second direction, and in the second region, the plurality of trenches extend in the second direction and are arranged at intervals in the first direction.

11. A manufacturing method for a semiconductor structure, comprising:
providing an interposer;
forming, in the interposer, lead-out electrode layers and a trench array comprising a plurality of trenches extending from a top surface of the interposer toward an interior of the interposer, the plurality of trenches further extending in a preset direction parallel to the top surface of the interposer; and
forming, in the trenches, a capacitor comprising at least a first electrode layer, a first capacitor dielectric layer, and a second electrode layer being sequentially stacked, the first capacitor dielectric layer covering a surface of the first electrode layer, and the second electrode layer covering a surface of the first capacitor dielectric layer; and
the lead-out electrode layers being electrically connected to the first electrode layer and/or the second electrode layer and extending in the preset direction.

12. The manufacturing method for a semiconductor structure according to claim 11, wherein the lead-out electrode layers are formed in the interposer before the trenches are formed, and subsequently the trenches are formed on both sides of the lead-out electrode layers,
wherein the lead-out electrode layers further extend in a depth direction of the trenches in the interposer, and each of the lead-out electrode layers is located between adjacent trenches and is electrically connected to only the first electrode layer.

13. The manufacturing method for a semiconductor structure according to claim 11, wherein each of the lead-out electrode layers comprises a first lead-out electrode layer and a second lead-out electrode layer, the first lead-out electrode layer is formed in the interposer before the trenches are formed, subsequently the trenches are formed on both sides of the first lead-out electrode layer, and the second lead-out electrode layer is formed in one trench after the capacitors are formed,
wherein the lead-out electrode layers further extend in a depth direction of the trenches in the interposer, the first lead-out electrode layer is located between adjacent trenches and is electrically connected to the first electrode layer, and the second lead-out electrode layer is electrically connected to the second electrode layer.

14. The manufacturing method for a semiconductor structure according to claim 11, wherein the forming a capacitor further comprises forming, after the second electrode layer is formed, a second capacitor dielectric layer, a third electrode layer, a third capacitor dielectric layer, and a fourth electrode layer being sequentially stacked in each of the trenches, the second capacitor dielectric layer covers a surface of the second electrode layer, the third electrode layer covers a surface of the second capacitor dielectric layer, the third capacitor dielectric layer covers a surface of the third electrode layer, and the fourth electrode layer covers a surface of the third capacitor dielectric layer; and
each of the lead-out electrode layers comprises a first lead-out electrode layer, a second lead-out electrode layer, a third lead-out electrode layer, and a fourth lead-out electrode layer, the first lead-out electrode layer is formed in the interposer before the trenches are formed, subsequently the trenches are formed on both sides of the first lead-out electrode layer, and the first lead-out electrode layer is located between adjacent trenches and is electrically connected to the first electrode layer; after the second electrode layer is formed and before the second capacitor dielectric layer is formed, the second lead-out electrode layer is formed, and the second lead-out electrode layer is located on an outer side of the trench at a first outermost side of the trench array and is electrically connected to the second electrode layer; after the third electrode layer is formed and before the third capacitor dielectric layer is formed, the third lead-out electrode layer is formed, and the third lead-out electrode layer is located on an outer side of the trench at a second outermost side of the trench array and is electrically connected to the third electrode layer; and after the fourth electrode layer is formed, the fourth lead-out electrode layer is formed in one trench to be electrically connected to the fourth electrode layer,
wherein the lead-out electrode layers further extend in a depth direction of the trenches in the interposer, the first outermost side and the second outermost side are two opposite sides of the trench array, directions of the two opposite sides are perpendicular to the preset direction, and the outer side of the trench is a side, which is away from an adjacent trench, of the trench located at the first outermost side or the second outermost side.

15. The manufacturing method for a semiconductor structure according to claim 11, wherein the forming a capacitor further comprises forming, after the second electrode layer is formed, a second capacitor dielectric layer, a third electrode layer, a third capacitor dielectric layer, and a fourth electrode layer being sequentially stacked in each of the trenches, the second capacitor dielectric layer covers a surface of the second electrode layer, the third electrode layer covers a surface of the second capacitor dielectric layer, the third capacitor dielectric layer covers a surface of the third electrode layer, and the fourth electrode layer covers a surface of the third capacitor dielectric layer; and
each of the lead-out electrode layers comprises a first lead-out electrode layer, a second lead-out electrode layer, and a third lead-out electrode layer; after the second electrode layer is formed and before the second capacitor dielectric layer is formed, the first lead-out electrode layer is formed in one trench, and the first lead-out electrode layer covers an upper surface of a portion, located at the bottom of the trench, of the second electrode layer and is electrically connected to the second electrode layer; after the third electrode layer is formed and before the third capacitor dielectric layer is formed, the second lead-out electrode layer is formed in the trench, and the second lead-out electrode layer covers an upper surface of a portion, located at the bottom of the trench, of the third electrode layer and is electrically connected to the third electrode layer; and after the fourth electrode layer is formed, the third lead-out electrode layer is formed in the trench, and the third lead-out electrode layer covers an upper surface of a portion, located at the bottom of the trench, of the fourth electrode layer and is electrically connected to the fourth electrode layer.

16. The manufacturing method for a semiconductor structure according to claim 11, wherein the forming a capacitor further comprises forming, after the second electrode layer is formed, a second capacitor dielectric layer, a third electrode layer, a third capacitor dielectric layer, and a fourth electrode layer being sequentially stacked in each of the trenches, the second capacitor dielectric layer covers a surface of the second electrode layer, the third electrode layer covers a surface of the second capacitor dielectric layer, the third capacitor dielectric layer covers a surface of the third electrode layer, and the fourth electrode layer covers a surface of the third capacitor dielectric layer; and
each of the lead-out electrode layers comprises a first lead-out electrode layer, a second lead-out electrode layer, a third lead-out electrode layer, and a fourth lead-out electrode layer; after the first electrode layer is formed and before the first capacitor dielectric layer is formed, the first lead-out electrode layer is formed in one trench, and the first lead-out electrode layer covers an upper surface of a portion, located at the bottom of the trench, of the first electrode layer and is electrically connected to the first electrode layer; after the second electrode layer is formed and before the second capacitor dielectric layer is formed, the second lead-out electrode layer is formed in the trench, and the second lead-out electrode layer covers an upper surface of a portion, located at the bottom of the trench, of the second electrode layer and is electrically connected to the second electrode layer; after the third electrode layer is formed and before the third capacitor dielectric layer is formed, the third lead-out electrode layer is formed in the trench, and the third lead-out electrode layer covers an upper surface of a portion, located at the bottom of the trench, of the third electrode layer and is electrically connected to the third electrode layer; and after the fourth electrode layer is formed, the fourth lead-out electrode layer is formed in the trench, and the fourth lead-out electrode layer covers an upper surface of a portion, located at the bottom of the trench, of the fourth electrode layer and is electrically connected to the fourth electrode layer.

17. The manufacturing method for a semiconductor structure according to claim 11, after the forming a capacitor, further comprising: forming an interlayer dielectric layer to cover top surfaces of the capacitors, and forming contact members, each of which penetrates through the interlayer dielectric layer to be electrically connected to one lead-out electrode layer and/or one first electrode layer and one second electrode layer.

18. The manufacturing method for a semiconductor structure according to claim 11, before the forming, in each of the trenches, a capacitor, further comprising: forming a bottom dielectric layer in the trench, to cover at least bottoms and sidewalls of the plurality of trenches,
the bottom dielectric layer being located between the interposer and the first electrode layer, and the first electrode layer covering a surface of the bottom dielectric layer.

19. A semiconductor device, comprising:
the semiconductor structure according to claim 1; and
chips located on the semiconductor structure,
the chips being electrically connected to the semiconductor structure through solder bumps and/or pads.
